(19) United States
(12) Patent Application Publication
(10) Pub. No.: US 2002/0164543 A1
(43) Pub. Date: Nov. 7, 2002

(54) Bi-layer photolithographic process

(75) Inventors: Chih-Yung Lin, Hsinchu Hsien (TW); Chun Cheng Chen, Pei-Tou Chen (TW)

Correspondence Address: J. C. PATENTS, 4 VENTURE, SUITE 250, IRVINE, CA, 92618, US

(73) Assignee: United Microelectronics Corp., Hsinchu (TW)

(21) Appl. No.: 09/897,680

(22) Filed: Jul. 2, 2001

(30) Foreign Application Priority Data
May 7, 2001 (TW) 90110808

(51) Int. Cl. G03F 7/36

(52) U.S. Cl. 430/313; 430/312; 430/330

(57) ABSTRACT

A bi-layer photolithographic process. A substrate having a material layer waiting to be patterned is provided. A non-photosensitive polymer layer and a top photoresist layer are sequentially formed over the material layer. A photo-exposure of the top photoresist layer is carried out followed by a photoresist development to form a patterned top photoresist layer that exposes a portion of the non-photosensitive polymer layer. Using the patterned top photoresist layer as a mask, a dry etching process is conducted using the patterned top photoresist layer as a mask and O₂/HBr as gaseous etchants. A portion of the non-photosensitive photoresist layer is removed to expose a portion of the material layer.

### CROSS-REFERENCE TO RELATED APPLICATION

This application claims the priority benefit of Taiwan application serial no. 90110808, filed May 7, 2001.

### BACKGROUND OF THE INVENTION

1. Field of the Invention

The present invention relates to a photolithographic process. More particularly, the present invention relates to a bi-layer photolithographic process.

2. Description of Related Art

Due to an increasing demand for integrated circuits with a high level of integration, size of electronic devices is gradually reduced. Photolithographic process is a very important step in the fabrication of semiconductor devices. Major steps related to the production of a metal-oxide-semiconductor (MOS) device such as the patterning of various thin films and the definition of doping areas involve photolithographic processes. In fact, photolithographic process is one of the determinant factors for producing devices having with a line width smaller than 0.18 μm.

To increase the level of integration, a light source with shorter wavelength is often used in photo-exposure. However, by shortening the light source wavelength to 193 μm, the polymeric molecules within a conventional single photoresist layer may easily dissociate leading to a fuzzy photoresist pattern after development. Consequently, there is little improvement in the level of integration.

A conventional method of resolving the molecular dissociation problem is to perform a bi-layer photolithographic process. First, a wafer substrate having a material layer thereon waiting to be patterned is provided. A thick non-photosensitive polymer layer and a thin upper photoresist layer are sequentially formed over the material layer. The upper photoresist layer is patterned. Thereafter, the non-photosensitive polymer layer is etched utilizing the difference in etching rate between the upper photoresist layer and the non-photosensitive polymer layer. Finally, the material layer is etched utilizing the difference in etching rate between the non-photosensitive high molecular weight layer and the material layer.

Because the upper photoresist layer in the bi-layer is relatively thin, light having a wavelength smaller than 193 μm can be used as a light source in photo-exposure for producing a clear pattern. The patterned upper photoresist layer is subsequently used as a mask to remove a portion of the non-photosensitive polymer layer. The patterned non-photosensitive polymer layer later serves as a mask for etching the substrate. Since the underlying wafer substrate must be protected from the etching step, the non-photosensitive polymer layer needs to have a definite thickness.

However, there are a few problems related to the application of a conventional bi-layer photolithographic process. For example, a large quantity of residue is attached to the sidewalls of the photoresist layer after development. Hence, a single photoresist method is still preferred over a bi-layer process when a light source having a wavelength greater than 193 μm is used.

### SUMMARY OF THE INVENTION

Accordingly, one object of the present invention is to provide a bi-layer photolithographic process that can effectively reduce the amount of residue attached to the sidewalls of the bi-layer after photoresist development.

To achieve these and other advantages and in accordance with the purpose of the invention, as embodied and broadly described herein, the invention provides a bi-layer photolithographic process. A substrate having a material layer waiting to be patterned is provided. A non-photosensitive polymer layer and a top photoresist layer are sequentially formed over the material layer. A photo-exposure of the top photoresist layer is carried out followed by a photoresist development to form a patterned top photoresist layer that exposes a portion of the non-photosensitive polymer layer. Using the patterned top photoresist layer as a mask, a dry etching process is conducted using the patterned top photoresist layer as a mask and O₂/HBr as gaseous etchants. A portion of the non-photosensitive photoresist layer is removed to expose a portion of the material layer.

In this invention, the gaseous etchant containing O₂/HBr can be directly developed at a relatively high surrounding temperature. In addition, the by-products produced by non-photosensitive polymer etching have no affiliation for the sidewalls of the photoresist bi-layer. Therefore, the attachment of residue on the bi-layer sidewalls is effectively prevented.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 through 5 are schematic cross-sectional views showing the steps in a bi-layer photolithographic process according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

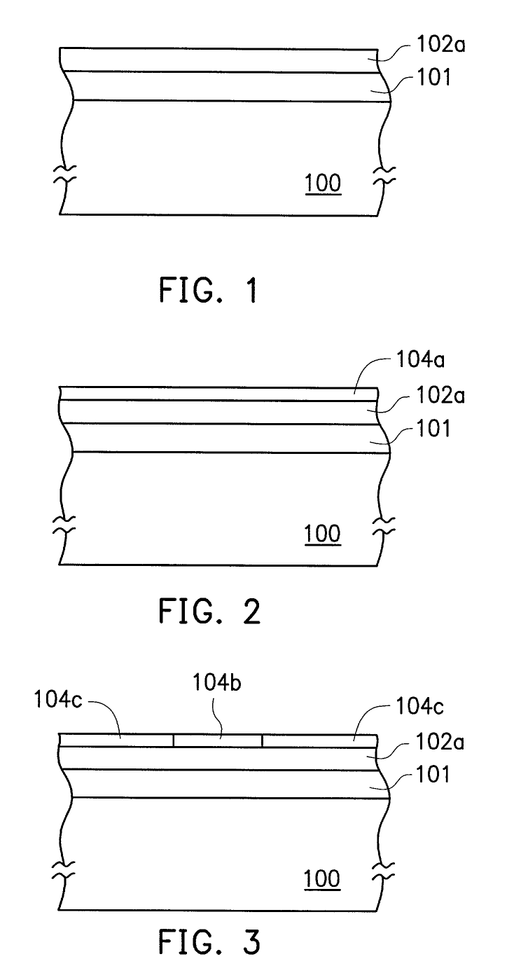

FIGS. 1 through 5 are schematic cross-sectional views showing the steps in a bi-layer photolithographic process according to one preferred embodiment of this invention. As shown in FIG. 1, a substrate 100 having a waiting-to-be-patterned material layer 101 thereon is provided. A non-photosensitive polymer layer 102a is formed over the material layer 101. The non-photosensitive polymer layer 102a can be formed by, for example, spin coating. The material layer can be a dielectric layer or a metallic layer, for example. A soft baking is conducted to remove any solvent inside the non-photosensitive polymer layer 102a. Hence, the original fluidic non-photosensitive polymer layer 102a is transformed into a solid layer and adhesive strength with the material layer 101 is increased. The soft baking can be carried out by thermal convection, infrared radiation or thermal conduction, for example.

As shown in FIG. 2, a thin top photoresist layer 104a is formed over the non-photosensitive polymer layer 102a. The top photoresist layer 104a can be negative photoresist layer or a positive photoresist layer formed by, for example, spin coating. A soft baking of the top photoresist layer 104a is carried out to drive away any solvent so that the original fluidic photoresist layer 104a is transformed into a solid layer and adhesion with the non-photoresist polymer layer is strengthened. The soft baking method includes thermal convection, infrared radiation or thermal conduction.

As shown in FIG. 3, a pattern is transferred to the top photoresist layer 104a by performing a photo-exposure. The top photoresist layer 104a is divided into exposed areas and unexposed areas. If the top photoresist layer 104a is a negative photoresist layer, the top photoresist layer 104b shown in FIG. 3 indicates the exposed areas while the top photoresist layer 104c indicates the unexposed areas. On the other hand, if the top photoresist layer 104a is a positive photoresist layer, the top photoresist layer 104c shown in FIG. 3 indicates the exposed areas while the top photoresist layer 104b indicates the unexposed areas.

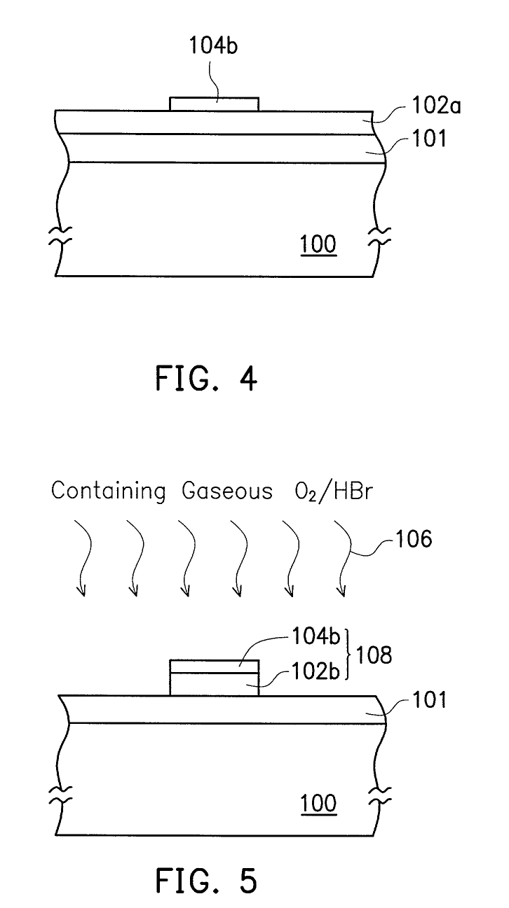

As shown in FIG. 4, a photoresist development is conducted to remove the top photoresist layer 104c and expose a portion of the non-photosensitive polymer layer 102a. The top photoresist layer 104c is removed by, for example, a wet developing process. If the top photoresist layer 104a is a negative photoresist layer, the developing agent will strengthen the exposed top photoresist layer 104b but will dissolve the unexposed top photoresist layer 104c. Conversely, if the top photoresist layer 104a is a positive photoresist layer, the developing agent will dissolve the exposed top photoresist layer 104c but will strengthen the unexposed top photoresist layer 104b.

As shown in FIG. 5, the exposed non-photosensitive polymer layer 102a is dry-etched using an etchant 106 containing gaseous O₂/HBr with the top photoresist layer 104b serving as a mask. A portion of the non-photosensitive polymer layer 102a is thereby removed and a portion of the material layer 101 is exposed. The non-photosensitive polymer layer 102a is removed by, for example, reactive ion etching. The top photoresist layer 104b and the non-photosensitive polymer layer 102b together form a bi-layer 108 above the material layer 101. To facilitate processing, an inert gas such as helium may be added to the O₂/HBr containing gaseous etchant 106, too.

Furthermore, of the O₂/HBr gases within the etchant 106, oxygen (O₂) flow rate is higher than hydrogen bromide (HBr) flow rate and the rate of flow of etchant 106 varies according to the etching device and circumstantial demands. For example, when oxygen flow rate is 100 sccm, hydrogen bromide flow rate is about 40 sccm.

In a conventional bi-layer photolithographic process, oxygen and sulfur dioxide (O₂/SO₂) are used as a dry etching agent. Because O₂/SO₂ gaseous etchant produces a large quantity of residue on bi-layer sidewalls with the amount of residues dependent on the processing temperature, large-scale production using conventional bi-layer process remains unfeasible.

This invention employs a dry-etching agent containing O₂/HBr so that no sticky substances are produced during a high-temperature etching of the non-photosensitive polymer layer. Also, it is noted that the high temperature adopted in the dry etching step above is the same or similar to the temperature used in the subsequent polysilicon etching. Without sticky residues attached to the photoresist sidewalls, resolution of photolithographic process, and ultimately, the level of circuit integration, are increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bi-layer photolithographic process, comprising:
providing a substrate having a material layer waiting to be patterned thereon;
forming a non-photosensitive polymer layer over the material layer;
forming a top photoresist layer over the non-photosensitive polymer layer;
performing a photo-exposure and transferring a pattern to the top photoresist layer such that the top photoresist layer is divided into exposed areas and unexposed areas;
developing the photo-exposed top photoresist layer to remove the top photoresist layer in the unexposed areas while retaining the top photoresist layer in the exposed areas; and
performing a dry etching to remove a portion of the non-photosensitive polymer layer and expose a portion of the material layer, using the patterned top photoresist layer as a mask and gaseous oxygen (O₂) and hydrogen bromide (HBr) as dry-etching agents.

2. The process of claim 1, wherein removing a portion of the non-photosensitive polymer layer includes reactive ion etching.

3. The process of claim 1, wherein removing a portion of the non-photosensitive polymer layer with oxygen and hydrogen bromide further includes introducing an inert gas.

4. The process of claim 3, wherein the inert gas includes helium.

5. The process of claim 1, wherein removing a portion of the non-photosensitive polymer using oxygen and hydrogen bromide includes introducing oxygen at a higher flow rate than hydrogen bromide.

6. The process of claim 1, wherein developing the photo-exposed photoresist layer includes conducting a wet development.

7. The process of claim 1, wherein the top photoresist layer includes a negative photoresist layer.

8. The process of claim 1, wherein forming the non-photosensitive polymer layer further includes:
coating non-photosensitive polymer material over the substrate; and
soft-baking to drive away any solvent within the non-photosensitive polymer material.

9. The process of claim 1, wherein forming the top photoresist layer further includes:
coating photoresist material over the non-photosensitive polymer layer; and
soft-baking to drive away any solvent within the top photoresist layer.

10. A bi-layer photolithographic process, comprising:
providing a substrate having a material layer waiting to be patterned thereon;
forming a non-photosensitive polymer layer over the material layer;
forming a top photoresist layer over the non-photosensitive polymer layer;
performing a photo-exposure to transfer a pattern to the top photoresist layer such that the top photoresist layer is divided into exposed areas and unexposed areas;
developing the photo-exposed top photoresist layer to remove the top photoresist layer in the exposed areas while retaining the top photoresist layer in the unexposed areas; and
performing a dry etching to remove a portion of the non-photosensitive polymer layer and expose a portion of the material layer, using the patterned top photoresist layer as a mask and gaseous oxygen (O₂) and hydrogen bromide (HBr) as dry-etching agents.

11. The process of claim 10, wherein removing a portion of the non-photosensitive polymer layer includes reactive ion etching.

12. The process of claim 10, wherein removing a portion of the non-photosensitive polymer layer with oxygen and hydrogen bromide further includes introducing an inert gas.

13. The process of claim 12, wherein the inert gas includes helium.

14. The process of claim 10, wherein removing a portion of the non-photosensitive polymer using oxygen and hydrogen bromide includes introducing oxygen at a higher flow rate than hydrogen bromide.

15. The process of claim 10, wherein developing the photo-exposed photoresist layer includes conducting a wet development.

16. The process of claim 10, wherein the top photoresist layer includes a positive photoresist layer.

17. The process of claim 10, wherein forming the non-photosensitive polymer layer further includes:
coating non-photosensitive polymer material over the substrate; and
soft-baking to drive away any solvent within the non-photosensitive polymer material.

18. The process of claim 10, wherein forming the top photoresist layer further includes:
coating photoresist material over the non-photosensitive polymer layer; and
soft-baking to drive away any solvent within the top photoresist layer.
